(19) United States
(12) Patent Application Publication
(10) Pub. No.: US 2026/0251689 A1
(43) Pub. Date: Aug. 27, 2026

(54) OVERHEAD POWER LINE SENSOR WITH MOTION DETECTION

(71) Applicant: Eaton Intelligent Power Limited, Dublin (IE)

(72) Inventors: Justin Bruce Johnson, Plymouth, MN (US); Rijad Bajramovic, Minneapolis, MN (US); Ryan L. Rausch, Delano, MN (US); Joshua S. Nosal, Athens, GA (US)

(21) Appl. No.: 19/062,911

(22) Filed: Feb. 25, 2025

(51) Int. Cl. G01R 31/08; G01P 1/00; G01P 1/02; G01R 19/25; G08B 21/18

(52) U.S. Cl. CPC G01R 31/085; G01P 1/023; G01P 1/06; G01R 19/2513; G08B 21/185

(57) ABSTRACT

An apparatus includes: a housing including a portion configured to be positioned around a suspended power line; a sensor in the portion configured to be positioned around the suspended power line; an accelerometer in the housing; a communications device in the housing; and an electronic control system in the housing, the electronic control system coupled to the sensor, the communications device, and the accelerometer. The electronic control system is configured to: determine whether a fault condition is present on the suspended power line based on information from the sensor; determine whether the suspended power line is in motion based on information from the accelerometer; and if a fault condition is present or if the suspended power line is in motion, control the communications device to send an alert to a receiver that is outside of the housing.

### TECHNICAL FIELD

This disclosure relates to an overhead power line sensor with motion detection.

### BACKGROUND

An electrical power grid includes one or more sources of electricity, one or more loads, and one or more mechanisms for distributing electrical power between the sources to the loads. The mechanisms for distributing electrical power include overhead power lines. Overhead power lines are power lines (for example, transmission lines, electrical cable, or wires) that are suspended above a surface.

### SUMMARY

In one aspect, an apparatus includes: a housing including a portion configured to be positioned around a suspended power line; a sensor in the portion configured to be positioned around the suspended power line; an accelerometer in the housing; a communications device in the housing; and an electronic control system in the housing, the electronic control system coupled to the sensor, the communications device, and the accelerometer. The electronic control system is configured to: determine whether a fault condition is present on the suspended power line based on information from the sensor; determine whether the suspended power line is in motion based on information from the accelerometer; and if a fault condition is present or if the suspended power line is in motion, control the communications device to send an alert to a receiver that is outside of the housing.

Implementations may include one or more of the following features.

The communications device may be a wireless communications device configured to send information to and receive information from a device separate from the apparatus via a wireless communication protocol.

The accelerometer may be configured to produce a freefall signal in response to falling, and the electronic control system may be configured to determine that the suspended power line is in motion based on the freefall signal.

The accelerometer may be configured to produce acceleration values that correspond to acceleration in one or more axes. The electronic control system may be configured to determine whether the suspended power line is in motion by analyzing the acceleration values. The electronic control system may be further configured to: determine whether the suspended power line is experiencing transient motion; and, if the suspended power line is experiencing transient motion, determine that the suspended power line is in motion. The electronic control system also may be configured to: determine an angle of the housing relative to a reference based on the acceleration values at a first time, determine an angle of the housing relative to the reference based on the acceleration values at a second time, compare the angle of the housing at the first time and the angle at the second time to determine whether the suspended power line is sagging; and if the suspended power line is sagging, control the communications device to send the alert.

The sensor may be a Rogowski coil.

The portion may have a closed state in which the portion defines an opening surrounded by the housing, and an opened state in which the opening is not surrounded by the housing; and the housing also may include an operable interface configured to transition the portion between the closed state and the opened state. The operable interface may be configured to be rotated to transition the portion between the closed state and the opened state. The operable interface may be on an exterior of the housing.

The accelerometer may be configured to produce an interrupt in response to a force being directly applied to an exterior of the housing, and the electronic control system may transitions the sensor from a first mode to a second mode in response to receiving the interrupt. The first mode may be an inactive mode and the second mode may be an active mode such that the force directly applied to the exterior of the housing wakes up the sensor.

In another aspect, a sensor includes: a housing including: a body, and an annulus extending from the body; an attachment device on an exterior of the housing, the attachment device configured to hold the housing to a suspended power line; an electrical measurement apparatus in the annulus; an accelerometer in the body; a communications device in the body; and an electronic control in the body, the electronic control coupled to the electrical measurement apparatus, the accelerometer, and the communications device.

Implementations may include one or more of the following features.

The sensor also may include an operable interface on an exterior of the body and coupled to the annulus; and the annulus may be configured to open in response to manipulation of the operable interface and to be closed to surround the suspended power line in response to manipulation of the operable interface.

The operable interface may be rotatable. The operable interface may include a ring configured to receive a hot stick.

The sensor also may include a mechanical linkage coupled to the operable interface and the annulus, and the mechanical linkage may include one or more arms that extend along an exterior of the annulus. The mechanical linkage may be spring-loaded.

The electronic control may be configured to detect motion in the suspended power line.

The accelerometer may be configured to provide an interrupt to the electronic control in response to detecting a force being applied to the exterior of the housing, and the electronic control may be configured to wake up the sensor in response to receiving the interrupt.

The electrical measurement apparatus may include a Rogowski coil.

In another aspect, a method includes: accessing electrical data from an electrical measurement apparatus in a housing that is attached to a suspended power line; determining whether a fault condition is present on the suspended power line based on information from the electrical measurement apparatus; accessing information from an accelerometer in the housing; determining whether the suspended power line is in motion based on information from the accelerometer; and if a fault condition is present on the suspended power line or if the suspended power line is in motion, controlling a communications device to send an alert to a receiver that is outside of the housing.

In some implementations, the method also includes: determining an angle of the housing relative to a reference; determining whether the suspended power line is sagging based on the angle; and if the suspended power line is sagging, controlling the communications device to send the alert to the receiver that is outside of the housing.

Implementations of any of the techniques described herein may include a system, an apparatus, or a method. The details of one or more implementations are set forth in the accompanying drawings and the description below. Other features will be apparent from the description and drawings, and from the claims.

### DRAWING DESCRIPTION

FIG. 1 is a block diagram of an example of a power system that includes a suspended power line.

FIG. 2 shows an example of a power system that includes a three-phase distribution path.

FIG. 3 shows an example of a sensor mounted to a suspended power line.

FIG. 4 is a block diagram of the sensor of FIG. 3.

FIG. 5A is a perspective exterior view of an example of a sensor.

FIG. 5B is a perspective view of another example sensor.

FIGS. 6A and 6B are front views of the sensor of FIG. 5A.

FIG. 7 is a flowchart of an example of a process for monitoring a suspended power line with a sensor.

### DETAILED DESCRIPTION

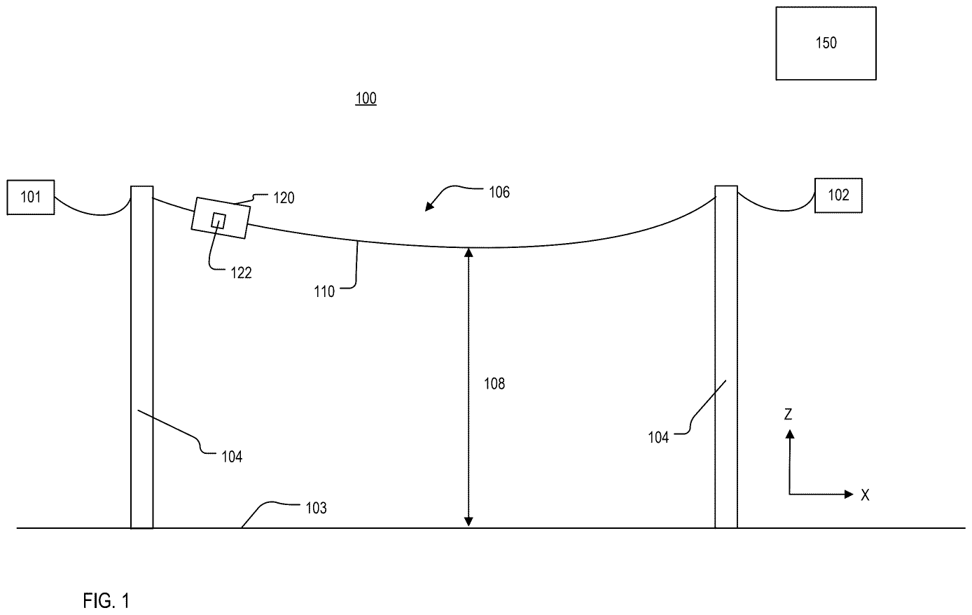

A sensor 120 for mounting on a suspended power line 110 is disclosed. FIG. 1 is a block diagram of a power system 100. The suspended power line 110 is part of the power system 100. As discussed below, the sensor 120 includes an accelerometer 122 that detects motion in the power line 110 and/or produces data that is used to detect motion in the power line 110. The motion of the power line 110 may be transient motion that is relatively short lived and caused by an acute, temporary event, or a gradual motion that occurs over a longer period of time. Examples of transient motion include, for example, line bucking or violent motion of the motion of the power line 110 cause by a fault or current surge, power line 110 slapping caused by high winds, and severing or breaking of the power line 110 due to falling objects. Examples of gradual motion include sagging of the power line 110 that can occur over days, weeks, or months. Regardless of whether the motion is transient or gradual in nature, unusual or unexpected motion of the power line 110 is often caused by failure of the power line 110 and/or the existence of conditions that may lead to failure of the power line 110.

When motion is detected in the power line 110, the sensor 120 provides a signal or alert to a remote station 150. The remote station 150 is separate from the sensor 120 and is not necessarily in the vicinity of the sensor 120. For example, the remote station 150 may be a utility central monitoring station, a workstation, a supervisory control and data acquisition (SCADA) network, or a mobile electronic device that is not near the sensor 120. In some implementations, the remote station 150 may be a gateway or other device that is connected to a remote network but is relatively near the sensor 120.

By monitoring the motion of the power line 110 and providing an alert to the remote station 150 when the motion of the power line 110 indicates that the power line 110 has failed, is failing, or is likely to fail, the sensor 120 improves the overall performance and reliability of the power system 100 and enhances the safety of the power system 100. Moreover, the sensor 120 also promotes efficient repair and maintenance of the power system 100. For example, the sensor 120 may be used to monitor suspended power lines in secluded or difficult to access areas that cannot be easily monitored and inspected manually.

Before discussing the sensor 120 in greater detail, an overview of the power system 100 is provided. The power system 100 distributes electricity from an electrical power source 101 to electrical loads 102 via a distribution path 106. The power system 100 may have an operating voltage of, for example, at least 1 kilovolt (kV), up to 27 kV, up to 38 kV, or greater than 38 kV. The power system 100 may operate at a fundamental frequency of, for example, 50 or 60 Hertz (Hz).

The power source 101 is any source that is capable of providing alternating current (AC) electrical current and may be a multi-phase power source. For example, the power source 101 may be an electrical generator that converts mechanical power into AC electrical current, a DC to AC converter, an AC to AC converter, a solar or wind farm, a fossil-fuel based power plant, or a distributed energy resource (DER). The electrical loads 102 may be any electrical equipment that receives electricity from the power source 101 and may include, for example, transformers, electrical machinery, motors, power converters, and/or electrical appliances and devices in a residential building, retail establishment, industrial facility, or municipal site. Moreover, the loads 102 may generate electrical power and/or the source 101 may consume electrical power.

Although the source 101 and the loads 102 are illustrated as being relatively near the sensor 120, this is not necessarily the case. For example, the source 101 and/or the loads 102 may be tens or hundreds of kilometers (km) away from the sensor 120.

The overhead distribution path 106 includes the power line 110, which is an electrical conductor mounted to two supports 104 and suspended above a surface 103. The power line 110 is nominally a distance 108 above the surface 103. However, the power line 110 is not rigid and may sag toward the surface 103. The nominal distance 108 is the expected distance between the power line 110 and the surface 103 during normal and typical operation of the power system 100.

The surface 103 is the surface of the earth, a foundation built into the surface of the earth, or a layer or object supported by the surface of the earth. For example, the surface 103 may be a grassy surface, a dirt surface, an asphalt surface, water, or a concrete surface. The surface 103 may be a surface that is underground. The supports 104 are any sturdy structure that can hold a power line. The supports 104 may be, for example, utility poles, pylons, mounting structures in a substation, frames, or transmission towers that are secured to or into the earth. The power line 110 may be referred to as an overhead power line or an overhead conductor.

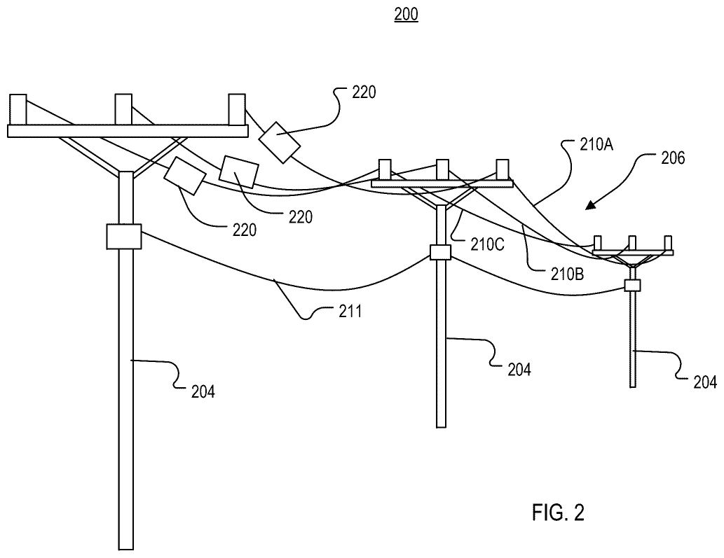

The power line 110 is any electrically conductive path. For example, the power line 110 may be a transmission line or an electrical cable. Although only one power line is shown in FIG. 1, the distribution path 106 may include more than one overhead conductor. The power system 100 may be a multi-phase (for example, three-phase) electrical network that provides electricity to commercial, industrial, municipal, and/or residential customers. For example, FIG. 2 shows a power system 200 that includes a three-phase distribution path 206. The three-phase distribution path 206 includes an overhead conductor 210A, 210B, 210C for each phase and an additional overhead conductor 211 for a neutral channel. The overhead conductors 210A, 210B, 210C, and 211 are mounted to supports 204 and suspended above a surface. A sensor 210 (which is an example of the sensor 120) is mounted to each overhead conductor 210A, 210B, 210C.

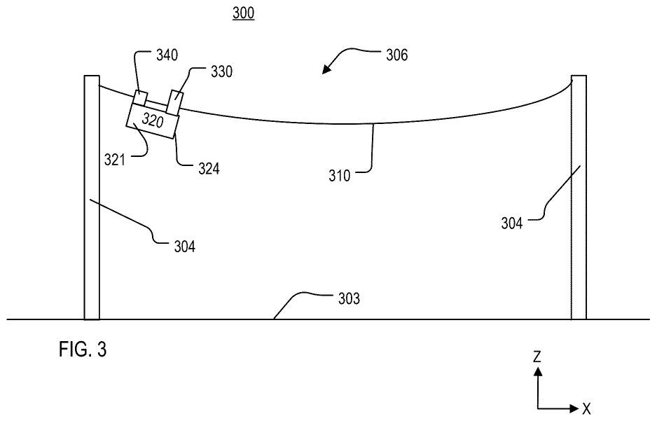

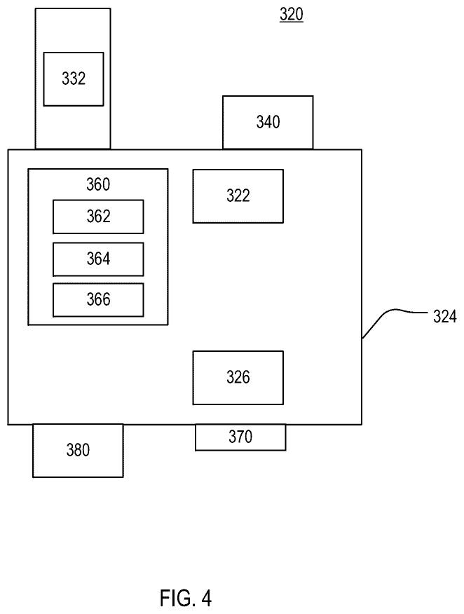

FIG. 3 shows a sensor 320 mounted to a suspended conductor (or suspended power line) 310 that distributes electricity. FIG. 4 is a block diagram of the sensor 320. The conductor 310 is attached to supports 304 and is suspended above a surface 303. The sensor 320 includes a housing 324, a portion 330 that extends from a body 321 of the housing 324. The portion 330 is part of the housing 324. When the sensor 320 is attached to the conductor 310, an opening defined by the portion 330 surrounds the conductor 310. The sensor 320 also includes an attachment device 340 that holds the sensor 320 to the conductor 310. The portion 330 encloses an electrical sensor 332 (FIG. 4). The attachment device 340 may be a clamp or any other mechanical connection that attaches to an exterior of the conductor 310.

Referring to FIG. 4, the sensor 320 includes an accelerometer 322 and a communications device 326. The accelerometer 322 measures acceleration in three axes (for example, x, y, and z) and provides an output that is an indication of the measured acceleration in each axis. The indication may be a numerical value in units of meters per second squared (m/s²). The communications device 326 is any device that is capable of transmitting data to a device that is separate from the sensor 320. The communications device 326 also may be capable of receiving data from a device that is separate from the sensor 320. The communications device 326 is any type of wireless communications device that is able to communicate with a separate device using a wireless communications protocol. For example, the communications device 326 may be a long-range communications device such as, for example, a cellular modem or a satellite modem, that communicates with a remote station that is many miles or kilometers away from the communications device 326. In some implementations, the communications device 326 may be a short-range communications device such as, for example, a Bluetooth device that communicates using the Bluetooth wireless protocol or a WiFi modem that communicates using a communications protocol based on the IEEE 801.11 standard. Other implementations are possible. For example, the communications device 326 may be a wireless device that sends and receives information using a radio communication technique such as LoRa (Long Range) or via a mesh network.

The electrical sensor 332 is any type of device that measures one or more properties of electricity that flows in the conductor 310. For example, the electrical sensor 332 may be a Rogowski coil, a current transformer (CT), and/or a voltage sensor. In implementations in which the electrical sensor 332 is a Rogowski coil, the Rogowski coil may be a split core Rogowski coil or a rope Rogowski coil. Regardless of the specific form of the electrical sensor 332, when the sensor 320 is attached to the conductor 310, the electrical sensor 332 generates data based on the sensed properties of electricity that flows in the conductor 310. For example, the electrical sensor 332 may produce values that represent an amplitude of the electrical current and/or voltage of the electricity that flows in the conductor 310.

The sensor 320 also includes an electronic control system 360. The electronic control system 360 includes an electronic processor 362, an electronic storage 364, and an input/output (I/O) interface 366. The electronic control system 360 may be a microcontroller. The electronic control system 360 may be powered by the electrical sensor 332. In these implementations, the sensor 320 harvests energy from the conductor 310 in addition to detecting motion of the suspended conductor 310 and faults on the suspended conductor 310. In some implementations, the sensor 320 includes a battery or other power source in the sensor 320 that is not necessarily powered by the electrical sensor 332.

The electronic processor 362 is one or more processors suitable for the execution of a computer program such as a general or special purpose microprocessor, and any one or more processors of any kind of digital computer. An electronic processor receives instructions and data from a read-only memory or a random-access memory or both. The electronic processor 362 may be any type of electronic processor, may be more than one electronic processor, and may include a general-purpose central processing unit (CPU), a graphics processing unit (GPU), a microcontroller, a field-programmable gate array (FPGA), and/or an application-specific integrated circuit (ASIC). The electronic storage 364 may be volatile memory, such as RAM. In some implementations, the electronic storage 364 may include both non-volatile and volatile portions or components. Examples of electronic storage may include solid state storage, magnetic storage, and optical storage. Solid state storage may be implemented in, for example, resistor-transistor logic (RTL), complementary metal-oxide semiconductor (CMOS), or carbon nanotubes, and may be embodied in non-volatile or volatile random-access memory.

The electronic storage 364 stores instructions, for example, as a computer program, software, and/or a subroutine, that, when executed, cause the electronic processor 362 to process data from the accelerometer 322 to detect motion in the power line 310, characterize detected motion, and/or detect severing of the power line 310. Additionally, the electronic storage 364 may include instructions to process data from the electrical sensor 332 and detect current and/or voltage faults on the power line 310. The electronic storage 364 also includes instructions to control the communications device 326. For example, the electronic storage 364 may store instructions that control the communications device 326 to issue an alert signal in response to detecting motion in the conductor 310.

The electronic storage 364 also may store information used to analyze data from the electrical sensor 332 and the accelerometer 322. For example, the electronic storage 364 may store current and/or voltage thresholds for detecting electrical faults on the conductor 310. In another example, the electronic storage 364 may store thresholds, templates, and/or signatures that are compared to data from the accelerometer 322 to determine whether the conductor 310 is moving and/or to characterize detected motion of the conductor 310 as a failure of the conductor 310 or an indication that the conductor 310 is likely to fail.

The electronic storage 364 also stores instructions that, when executed, process an interrupt or interrupt(s) from the accelerometer 322 and cause the sensor 320 to transition to a different mode in response. For example, the accelerometer 322 may be configured to generate an interrupt in response to a force applied to the exterior of the housing 324. The force may be, for example, a force generated by a human operator tapping or pressing on the housing 324 with a hot stick, rod, or other element. When force is applied to the exterior of the housing 324, the accelerometer 322 detects motion caused by the force. The accelerometer 322 provides an interrupt to the electronic control system 360, which detects that a force has been applied to the exterior of the housing 324. In response to detecting the force applied to the exterior of the housing 324, the electronic control system 360 transitions the sensor 320 into a different mode. For example, tapping on the exterior of the housing 324 may turn the sensor 320 on and/or off. In another example, tapping on the exterior of the housing 324 may place the sensor 320 into a low-power mode or wake the sensor 320 up from a low-power mode.

The sensor 320 also includes an operable interface 380 that allows a user to attach the sensor 320 to the conductor 310 and to remove the sensor 320 from the conductor 310. For example, the operable interface 380 may be a hook or knob that is turned to open and close the portion 330 and to clamp or unclamp the attachment device 340 from the conductor 310.

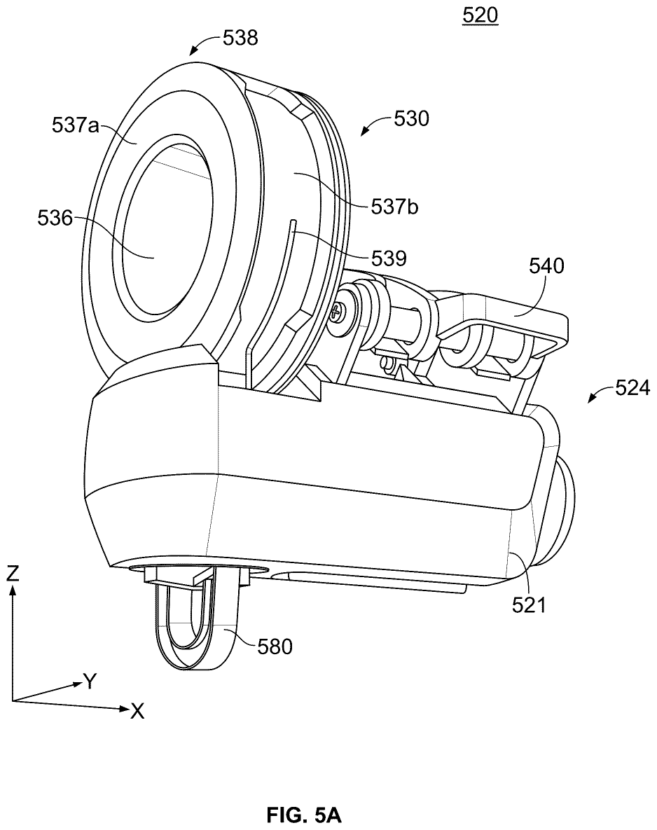

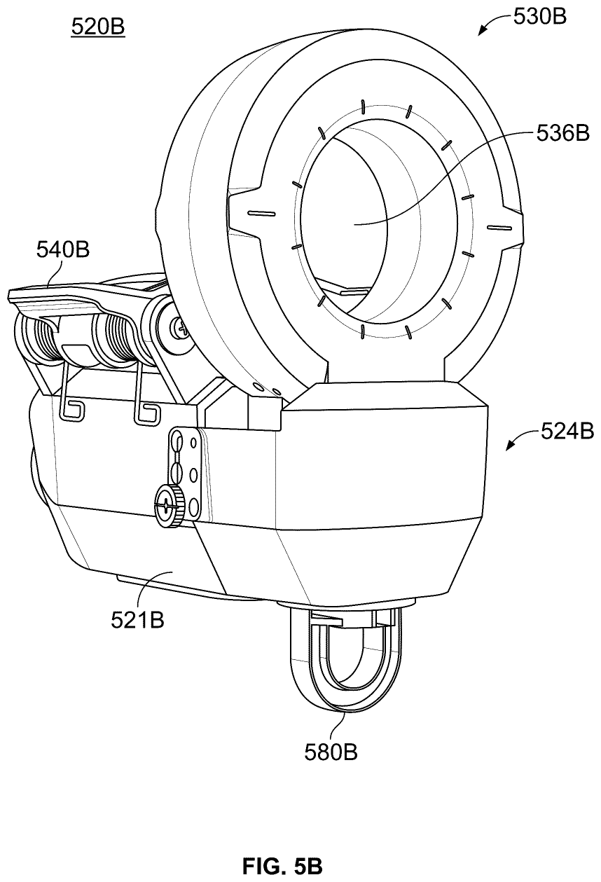

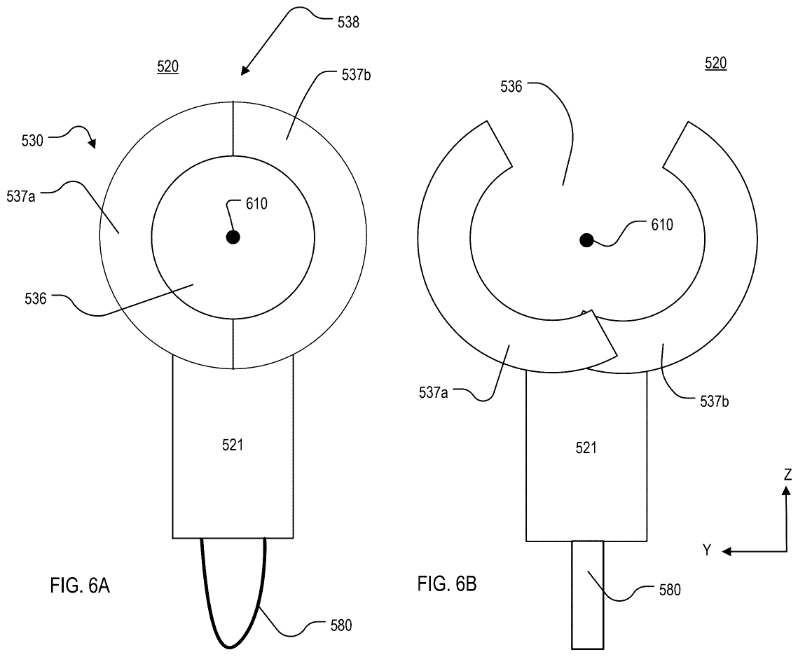

FIG. 5A is a perspective exterior view of a sensor 520. The sensor 520 is an example of a sensor for monitoring a power line for electrical faults and motion. For example, the interface 580 may be operated by pushing and pulling or by sliding instead of by rotation. The sensor 520 can be attached to the power line 110; to any of the power lines 210A, 210B, 210C; to the power line 310; or to the power line 610 (FIGS. 6A and 6B). The sensor 520 includes a housing 524, which has a body portion 521 and a sensor portion 530 that extends from the body portion 521. The sensor 520 also includes an attachment device 540 on an exterior of the body portion 521. The attachment device 540 is a purely mechanical clamping mechanism that holds the sensor 520 to a power line. For example, the attachment device 540 may include two arms that close by moving toward each other to grasp the power line in response to a trigger and remain closed and attached to the power line by a spring force that holds the arms in the closed position.

The body portion 521 and the sensor portion 530 include interior regions that contain components, such as those discussed with respect to FIG. 4. For example, the body portion 521 houses an electronic control system, an accelerometer, and a communications device. The sensor portion 530 is an annulus with an opening 536. The sensor portion 530 includes an electrical sensor such as a Rogowski coil. The sensor portion 530 has a closed state and an opened state. The sensor portion 530 is in the closed state in FIG. 5A. Referring also to FIGS. 6A and 6B, which are front views of the sensor 520, the sensor portion 530 includes a first half 537a and a second half 537b. When the sensor portion 530 is in the closed state (such as in FIGS. 5A and 6A), the first half 537a and the second half 537b are in physical contact and the first half 537a and the second half 537b surround the opening 536.

The sensor 520 also includes an operable interface 580 that extends from the body portion 521. The operable interface 580 is a hook that is sized to receive a hotstick and can be rotated to open and close the sensor portion 530. When the operable interface 580 is rotated in a first direction, a mechanical link 539 causes the top side 538 of the first half 537a and the second half 537b to separate such that the top side 538 is open and the opening 536 is not completely surrounded. Additionally, rotating the interface 580 also places the attachment device 540 in the open position. With the sensor portion 530 in the opened state and the attachment device 540 in the opened position, the sensor 520 is pushed toward the power line 610 until the attachment device 540 is in contact with the exterior of the power line 610. The interface 580 is rotated again to close the attachment device 540 onto the exterior of the power line 610 and to close the sensor portion 530 around the power line 610 with the power line centered in the opening 536. In this way, the sensor 520 is attached to the power line 610. Once attached to the power line, the sensor 520 monitors the motion of the power line 610 and the electricity that flows in the power line.

Other implementations of the sensor 520 are possible. For example, the interface 580 is discussed as being operated by rotation, but may be implemented in other ways. FIG. 5B is a perspective view of another sensor 520B, which is another example a sensor for monitoring a power line for electrical faults and motion. The sensor 520B includes a housing 524B, which has a body portion 521B and a sensor portion 530B that extends from the body portion 521B. The sensor 520B also includes an attachment device 540B on an exterior of the body portion 521B. The attachment device 540 is a purely mechanical clamping mechanism that holds the sensor 520 to a power line. For example, the attachment device 540 includes clamps 548B that secure the sensor 520B to the power line and springs 549B that apply a force to the clamps 548B such that the sensor 520B remains attached to the power line until intentionally removed.

The sensor portion 530B encloses a Rogowski coil or other current measuring device and defines an opening 536B. When the sensor 530B is attached to a power line, the power line passes through the opening 536B such that the current measuring device in the sensor portion 530B is able to measure electrical current that flows in the power line.

The sensor 520B also includes an operable interface 580B that extends from the body portion 521B. The operable interface 580B is a hook that is sized to receive a hotstick and can be rotated to open and close the sensor portion 530B in a manner similar to that discussed above with respect to FIGS. 6A and 6B.

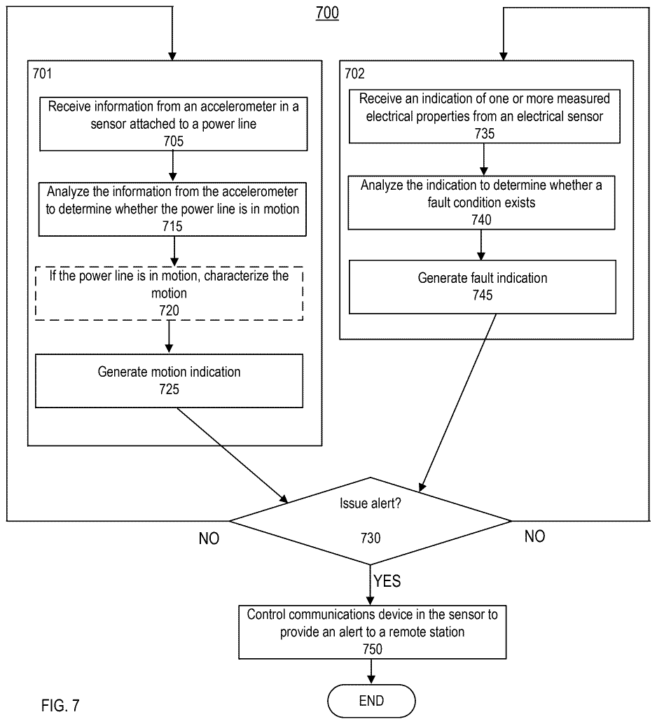

FIG. 7 is a flowchart of a process 700. The process 700 is an example of a process for monitoring a suspended power line with a sensor (such as the sensor 120, 220, 320, 520, or 520B) that is mounted to a suspended power line. The process 700 may be performed by the electronic processor 362 of the control system 360 (FIG. 4). To provide an example, the process 700 is discussed with respect to the sensor 320 and the power line 310 (FIG. 3). The process 700 includes two subprocesses 701 and 702. The subprocess 701 determines whether or not the suspended power line 310 is in motion, and the subprocess 702 determines whether or not a fault condition exists on the suspended power line 310. The subprocesses 701 and 702 are independent and may be performed at different rates and/or without the other subprocess.

The subprocess 701 receives information from the accelerometer 322 (705). The accelerometer is in the housing 324 of the sensor 320. The information from the accelerometer 322 includes numerical values that each represent an acceleration of the housing 324 in one axis at a particular time. Because the housing 324 is attached to the suspended power line 310, the acceleration of the housing 324 in a particular axis is representative of the acceleration of the power line 310 in that axis.

The information from the accelerometer 322 is analyzed to determine whether the suspended power line 310 is in motion (715). For example, acceleration in each axis as measured by the accelerometer 322 may be compared to a threshold. If the measured acceleration exceeds the threshold in one or more axis, the suspended power line 310 is determined to be in motion. In another example, if the information from the accelerometer shows no acceleration other than acceleration due to gravity in all axes, the suspended power line 310 is free fall and is determined to be in motion.

Moreover, in some implementations, the information from the accelerometer 322 is analyzed to determine whether the power line 310 is sagging, has sagged, or is moving gradually due to sagging. To determine whether the power line 310 is sagging, the information from the accelerometer 322 is analyzed to determine the angle of a body 321 of the sensor 320 relative to a fixed reference (for example, the X or Z direction in FIG. 3) at a first time. Information from the accelerometer 322 collected at a second time is analyzed to determine the angle of the body 321 of the sensor 320 relative to the same fixed reference at a later time. By comparing the angle of the body 321 of the sensor 320 at the first time and the later time, gradual motion of the power line 310 can be detected. For example, if the angle of the body 321 remains the same or nearly the same over time, the power line 310 is not sagging. In some implementations, the difference between the angle of the sensor 320 relative to the fixed reference at the first time and the angle of the sensor 320 relative to the fixed reference at the second time is compared to a pre-determined threshold. If the absolute value of the difference exceeds the threshold, the power line 310 is determined to be sagging.

Sagging of the power line 310 may be determined in other ways. For example, the angle of the body 321 relative to the reference at one point in time may be determined and compared to a pre-defined expected angle. In this example, if the difference between the measured angle of the body 321 and the expected angle of the body 321 exceeds the threshold, the power line 310 is determined to be sagging.

In some implementations, if the suspended power line 310 is determined to be in motion, the motion is characterized (720). For example, the acceleration measured by the accelerometer 322 may be stored in the electronic storage 364 and a time series of the acceleration in one or more axes may be analyzed to determine if the power line 310 is vibrating or experiencing a particular form of periodic motion.

The subprocess 701 may be implemented without the motion characterization (720). In other words, the subprocess 701 may be implemented to detect motion of the suspended power line or to detect motion of the suspended power line 310 and to characterize the detected motion.

A motion indication is generated (725) and provided to an alert monitor (730). The motion indication is a flag, value, or signal that indicates whether or not motion was detected in the power line 310. For example, the motion indication may be a binary variable that has a value of one (1) when the suspended power line is in motion and zero (0) when no motion is detected. In implementations that include the motion characterization (720), the motion indication also may provide information regarding the motion of the suspended power line 310. For example, in these implementations, the motion indication may have a value that corresponds to the type of motion, such as, a change in the angle (or sag), or the presence of periodic or quasi-periodic motion of the suspended power line 310.

The subprocess 702 monitors the suspended power line for electrical faults. An indication of one or more electrical properties measured by the electrical sensor 332 is received (735). The indication may include, for example, voltage and/or current measurements. The indication is analyzed to determine whether there is a fault condition on the suspended power line (740). For example, the voltage and/or current measurements may be compared to one or more fault thresholds stored on the electronic storage 364, and a fault condition is determined to exist if the voltage and/or current measurements exceed the fault threshold(s).

A fault indication is generated (745) and provided to the alert monitor (730). The fault indication may be a binary variable that has a value of one (1) if a fault condition is present on the suspended power line 310 and a value of (0) if no fault condition is present.

The alert monitor analyzes the motion indication from the subprocess 701 and/or the fault indication from the subprocess 702 to determine whether to issue an alert. In some implementations, the subprocess 701 and the subprocess 702 are performed in parallel and the alert monitor reviews both indications to determine whether to issue an alert. For example, in these implementations, the alert monitor may be configured to always issue an alert if there is a fault condition on the suspended power line 310 regardless of whether or not there is also detected motion. In some implementations, the subprocess 701 and 702 are performed in parallel by not at the same rate. In these implementations, the alert monitor may be configured to generate an alert whether either the motion indicator shows detected motion or the fault indication shows a detected fault condition.

If the alert monitor determines that an alert is not to be generated at (730), the process continues to monitor the suspended power line 310 by performing the subprocess 701 and/or the subprocess 702 again. If the alert monitor determines that an alert is to be generated, the process 700 advances to (750) to control the communications device 326 to provide an alert to a device that is separate from the sensor 320. The alert may provide information about the conditions that caused the alert. For example, the alert may provide an indication that there is a fault condition on the suspended power line 310 and/or that the suspended power line 310 is experiencing unusual motion. After the alert is generated, the process 700 ends or continues to monitor the suspended power line 310 by performing the subprocesses 701 and/or 702.

These and other implementations are within the scope of the claims.

What is claimed is:

1. An apparatus comprising:
a housing comprising a portion configured to be positioned around a suspended power line;
a sensor in the portion configured to be positioned around the suspended power line;
an accelerometer in the housing;
a communications device in the housing; and
an electronic control system in the housing, the electronic control system coupled to the sensor, the communications device, and the accelerometer, wherein the electronic control system is configured to:
determine whether a fault condition is present on the suspended power line based on information from the sensor;
determine whether the suspended power line is in motion based on information from the accelerometer; and
if a fault condition is present or if the suspended power line is in motion, control the communications device to send an alert to a receiver that is outside of the housing.

2. The apparatus of claim 1, wherein the communications device is a wireless communications device configured to send information to and receive information from a device separate from the apparatus via a wireless communication protocol.

3. The apparatus of claim 1, wherein the accelerometer is configured to produce a freefall signal in response to falling, and the electronic control system is configured to determine that the suspended power line is in motion based on the freefall signal.

4. The apparatus of claim 1, wherein the accelerometer is configured to produce acceleration values that correspond to acceleration in one or more axes.

5. The apparatus of claim 4, wherein the electronic control system is configured to determine whether the suspended power line is in motion by analyzing the acceleration values.

6. The apparatus of claim 5, wherein the electronic control system is further configured to determine whether the suspended power line is experiencing transient motion; and, if the suspended power line is experiencing transient motion, determine that the suspended power line is in motion.

7. The apparatus of claim 5, wherein the electronic control system is further configured to: determine an angle of the housing relative to a reference based on the acceleration values at a first time, determine an angle of the housing relative to the reference based on the acceleration values at a second time, compare the angle of the housing at the first time and the angle at the second time to determine whether the suspended power line is sagging; and
if the suspended power line is sagging, control the communications device to send the alert.

8. The apparatus of claim 1, wherein the sensor is a Rogowski coil.

9. The apparatus of claim 1, wherein the portion has a closed state in which the portion defines an opening surrounded by the housing, and an opened state in which the opening is not surrounded by the housing; and the housing further comprises an operable interface configured to transition the portion between the closed state and the opened state.

10. The apparatus of claim 9, wherein the operable interface is configured to be rotated to transition the portion between the closed state and the opened state.

11. The apparatus of claim 9, wherein the operable interface is on an exterior of the housing.

12. The apparatus of claim 1, wherein the accelerometer is configured to produce an interrupt in response to a force being directly applied to an exterior of the housing, and the electronic control system transitions the sensor from a first mode to a second mode in response to receiving the interrupt.

13. The apparatus of claim 12, wherein the first mode comprises an inactive mode and the second mode comprises an active mode such that the force directly applied to the exterior of the housing wakes up the sensor.

14. A sensor comprising:
a housing comprising: a body, and an annulus extending from the body;
an attachment device on an exterior of the housing, the attachment device configured to hold the housing to a suspended power line;
an electrical measurement apparatus in the annulus;
an accelerometer in the body;
a communications device in the body; and
an electronic control in the body, the electronic control coupled to the electrical measurement apparatus, the accelerometer, and the communications device.

15. The sensor of claim 14, further comprising:
an operable interface on an exterior of the body and coupled to the annulus; and wherein the annulus is configured to open in response to manipulation of the operable interface and to be closed to surround the suspended power line in response to manipulation of the operable interface.

16. The sensor of claim 15, wherein the operable interface is rotatable.

17. The sensor of claim 16, wherein the operable interface comprises a ring configured to receive a hot stick.

18. The sensor of claim 15, further comprising a mechanical linkage coupled to the operable interface and the annulus, and wherein the mechanical linkage comprises one or more arms that extend along an exterior of the annulus.

19. The sensor of claim 18, wherein the mechanical linkage is spring-loaded.

20. The sensor of claim 14, wherein the electronic control is configured to detect motion in the suspended power line.

21. The sensor of claim 14, wherein the accelerometer is configured to provide an interrupt to the electronic control in response to detecting a force being applied to the exterior of the housing, and the electronic control is configured to wake up the sensor in response to receiving the interrupt.

22. The sensor of claim 14, wherein the electrical measurement apparatus comprises a Rogowski coil.

23. A method comprising:
accessing electrical data from an electrical measurement apparatus in a housing that is attached to a suspended power line;
determining whether a fault condition is present on the suspended power line based on information from the electrical measurement apparatus;
accessing information from an accelerometer in the housing;
determining whether the suspended power line is in motion based on information from the accelerometer; and
if a fault condition is present on the suspended power line or if the suspended power line is in motion, controlling a communications device to send an alert to a receiver that is outside of the housing.

24. The method of claim 23, further comprising:
determining an angle of the housing relative to a reference;
determining whether the suspended power line is sagging based on the angle; and
if the suspended power line is sagging, controlling the communications device to send the alert to the receiver that is outside of the housing.
